(19) United States
(12) Patent Application Publication
(10) Pub. No.: US 2021/0066525 A1
(43) Pub. Date: Mar. 4, 2021

(54) OPTICAL ASSEMBLY WITH PHOTOVOLTAIC LAYER

(71) Applicant: Leo Volfson, Del Mar, CA (US)

(72) Inventor: Leo Volfson, Del Mar, CA (US)

(21) Appl. No.: 16/559,545

(22) Filed: Sep. 3, 2019

(51) Int. Cl. H01L 31/054; G02B 7/183; H01L 31/12; H01L 31/0463

(52) U.S. Cl. CPC H01L 31/0543; G02B 7/183; H01L 31/0488; H01L 31/0463; H01L 31/12

(57) ABSTRACT

Systems and devices can include a first optical element and a second optical element, the first and second optical elements transparent to visible light; and a photovoltaic element residing between the first optical element and the second optical element, the photovoltaic element transparent to visible light, the photovoltaic element to generate electricity based on the absorption of ultraviolet (UV) and near-infrared (NIR) light. The photovoltaic element can include a conductive element to conduct electricity generated from the absorption of UV and NIR light.

### BACKGROUND

Photovoltaic elements can be used to generate direct current through the absorption light (e.g., sunlight) as a source of energy. Photovoltaic elements rely on the photovoltaic effect, in which electrons or other charge carriers are excited to a higher-energy state by light absorption.

### SUMMARY

Aspects of the embodiments include an apparatus that can include a first optical element and a second optical element, the first and second optical elements transparent to visible light; and a photovoltaic element residing between the first optical element and the second optical element, the photovoltaic element transparent to visible light, the photovoltaic element to generate electricity based on the absorption of ultraviolet (UV) and near-infrared (NIR) light. The photovoltaic element can include a conductive element to conduct electricity generated from the absorption of UV and NIR light.

Aspects of the embodiments can include a system that includes an optical assembly having a first optical element and a second optical element, the first and second optical elements transparent to visible light; and a photovoltaic element residing between the first optical element and the second optical element, the photovoltaic element transparent to visible light, the photovoltaic element to generate electricity based on the absorption of ultraviolet (UV) and near-infrared (NIR) light. The photovoltaic element can include a conductive element to conduct electricity generated from the absorption of UV and NIR light. A light emission device can be electrically connected to the conductive element; the photovoltaic element to provide electricity to the light emission device.

In some embodiments, one or both of the first or second optical elements include a lens.

In some embodiments, one or both of the first or second optical elements comprises an aim assist marking.

In some embodiments, the aim assist marking comprises a reticle.

In some embodiments, the conductor is coupled to a wire by a wire-bond or a solder bond.

In some embodiments, the first or second optical material comprises an optically transparent coating.

In some embodiments, the photovoltaic element comprises an organic active layer.

In some embodiments, the light emission device comprising a power supply, the conductive element electrically connected to the light emission device through the power supply, the power supply to provide power to the light emission device.

In some embodiments, one or both of the first or second optical elements comprises an aim assist marking; and wherein the light emission device is positioned to illuminate the first or second optical elements.

In some embodiments, the aim assist marking comprises a reticle.

In some embodiments, the system comprises a display device, and wherein light emission device is to illuminate the internal display device.

In some embodiments, the light emission device comprises a laser or light emitting diode.

In some embodiments, an optical train is included to reflect light emitted from the light emission device to one or both of the first or second optical element.

In some embodiments, the system comprises a scope, the scope housing the optical assembly.

In some embodiments, the scope houses the light emission device.

In some embodiments, the system comprises a holographic sight or a red-dot sight, and wherein the light emission device comprises a holographic emitter or a red-dot emitter.

In some embodiments, the system comprises a wearable optical device, the optical assembly secured by the wearable optical device.

In some embodiments, the wearable optical device comprises one of glasses, sunglasses, goggles, or augmented reality lenses.

In some embodiments, the wearable optical device comprises a display device, the display device electrically connected to the photovoltaic element.

### BRIEF DESCRIPTION OF THE DRAWINGS

FIG. 1A is a schematic diagram of an example optical assembly with a photovoltaic layer in accordance with embodiments of the present disclosure.

FIG. 1B is a schematic diagram of a charge collection mechanism of a photovoltaic element in accordance with embodiments of the present disclosure.

FIG. 2 is a schematic diagram illustrating example operation of a device that includes an optical component with a photovoltaic layer in accordance with embodiments of the present disclosure.

FIG. 3A is a schematic diagram of an example optical device that includes various optional locations for optical assemblies with a photovoltaic layers in accordance with embodiments of the present disclosure.

FIG. 3B is a schematic diagram of an example photovoltaic layer with a reticle lens assembly in accordance with embodiments of the present disclosure.

FIGS. 4A-B a schematic diagram of example optical devices that includes an optical assembly with a photovoltaic layer in accordance with embodiments of the present disclosure.

FIG. 5 is a schematic diagram of another example optical device that includes an optical assembly with a photovoltaic layer and an internal display device in accordance with embodiments of the present disclosure.

FIG. 6 is a schematic diagram of an example wearable optical device that includes an optical assembly with a photovoltaic layer in accordance with embodiments of the present disclosure.

Figures are not drawn to scale.

### DETAILED DESCRIPTION

This disclosure describes the integration or addition of a photovoltaic layer to an optical element. In embodiments, the photovoltaic layer can transparent or semi-transparent to visible light, while absorbing light in the ultraviolet and/or infrared (IR) wavelengths for charge excitation.

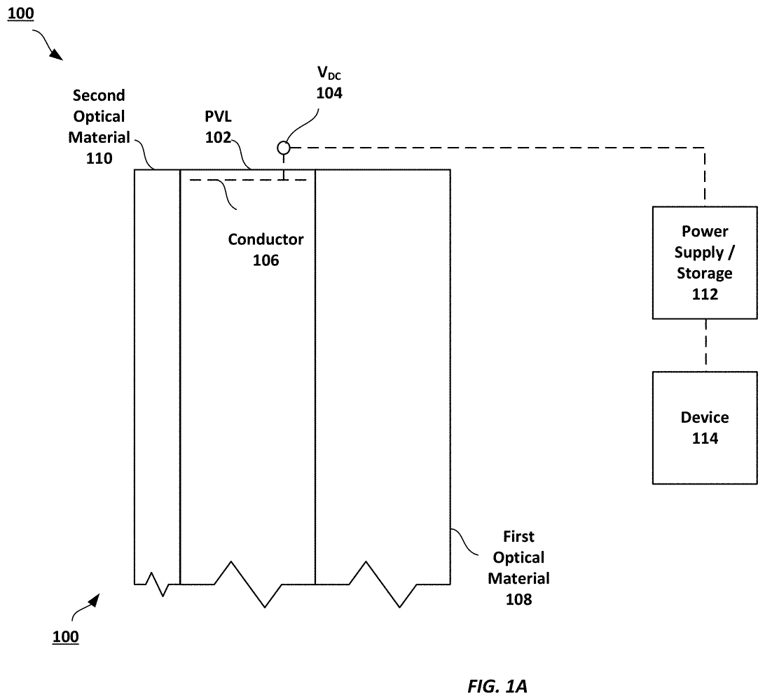

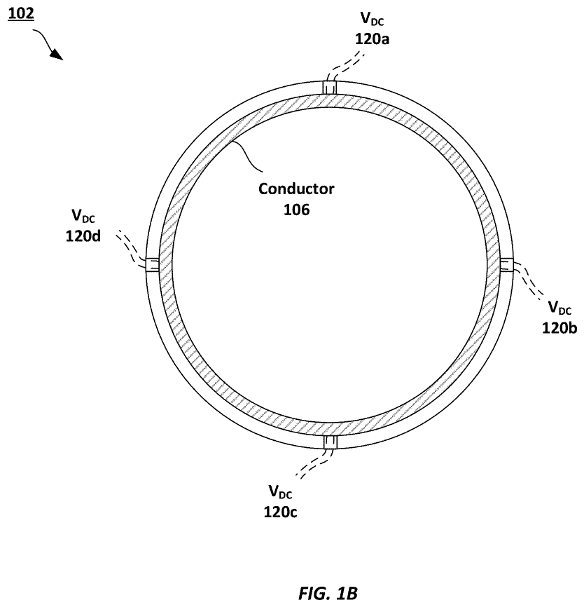

FIG. 1A is a schematic diagram of an example optical assembly 100 with a photovoltaic layer (PVL) 102 in accordance with embodiments of the present disclosure. PVL 102 can include a transparent or semi-transparent photovoltaic material, such as that used in solar cells. The PVL 102 can absorb ultraviolet (UV) and infrared (IR) and/or near IR (NIR) light to excite electrons or other charge carriers within PVL 102 to generate electricity (output as V_{DC} 104 through conductor 106). A conductor can be coupled to the PVL 102 to carry current to power supply/storage 112. For example, a conductive wire can be wire bonded to a terminal on the PVL 102 through known wire bonding techniques. Other mechanisms for capturing the electrical output 104 from PVL 102 can be used, such as

The term transparent as used herein encompasses an average visible transparency of a 45% or more (e.g., for light traversing straight through the optical element). The term semi-transparent as used herein encompasses an average visible transparency of a straight through beam of approximately 10%-45%. In some embodiments, PVL 102 can achieve up to 90% optical transparency, while absorbing UV and NIR light.

Near-infrared (NIR) as recited herein can include light of wavelengths in the range from approximately 650 to about 850 nanometers (nm). Ultraviolet (UV) as recited herein is defined as light having wavelengths less than approximately 450 nm. The use of an active layer having absorption in the NIR and the UV allows for the use of selective high-reflectivity near-infrared mirror coatings to optimize device performance while also permitting high transmission of visible light through the entire device. Visible light as recited herein is defined as light having wavelengths to which the human eye has a significant response, from about 450 to about 650 nm.

Optical assembly 100 can include PVL 102 residing between two optical elements: first optical element 108 and second optical element 110. The first and second optical elements 108 and 110, respectively, can be any type of optically transparent element, such as lenses, doublets, mirrors, glass, charge coupled devices, optical coatings, thin films, a combination of any of the former examples, etc. The PVL 102 can be a film applied on one of the first or second optical elements through known deposition techniques. The PVL 102 may be formed as heterojunction solar cells with an organic active layer, such as chloroaluminum phthalocyanine (CIAIPc) or SnPc as a donor and a molecular active layer such as C₆₀ acting as an acceptor and having peak-absorption in the UV and NIR solar spectrum. The PVL 102 can also include a conductor 106 integrated into the film. Conductor 106 can facilitate charge flow from the PVL 102 out to an output 104. Output 104 can be coupled to a power supply or power storage module 112, which can store power and/or provide power to a device 114. In embodiments, power supply/storage module 112 can receive power from other sources, such as batteries or external power, and the PVL 102 can augment power delivered to the power supply/storage module 112.

Device 114 can be an electrical device that uses power within the limits of the power generation of the PVL 102. For example, in some embodiments, the PVL 102 can generate from 8-24 mW of power. Device 114 can be, for example, a diode that consumes 1-to 5 mW of power, such as those used in laser or LED sites, red-dot sights, or holographic sights. Device 114 can be a display device, such as an internal display for a scope, an augmented reality display for glasses, a metrics display for goggles, etc. By way of example, a display can be powered using 5-10 mW.

More generally, device 114 can be a system that includes a power supply/storage module 112. Device 114 can use power input into power supply/storage 112 to provide power to electrical components of the system. For example, device 114 can be a camera that includes a charged coupled device, a flash, a display screen, a radio, and other electrical components. Power received into the power supply/storage 112 can be used to power or partially power any of these components. Power supply/storage 112 can also receive power from other power sources, such as batteries, wall outlets, other solar cells, etc. The PVL 102 can supply some or all of the power received into the power supply/storage 112.

Power supply/storage 112 can be any type of power storage and/or distribution module. For example, power supply/storage 112 can store charge received from the PVL 102 for later use. In embodiments, the power supply/storage 112 can distribute electrical power received by PVL 102 to one or more devices. In embodiments, the power supply/storage 112 can do one or both of power storage and/or supply.

FIG. 1B is a schematic diagram of a charge collection mechanism of a photovoltaic element 102 in accordance with embodiments of the present disclosure. Photovoltaic element 102 can include a conductor 106 embedded in the structure of the element. Conductor 102 can conduct charge carriers from the photovoltaic element 102 towards one or more outputs 120a-d. In embodiments, the photovoltaic element 102 can include a single output or multiple outputs, depending on the implementation choice. One or more outputs 120a-d can be connected to a wire, plate, terminal, or other type of terminal that can electrically connect the photovoltaic element 102 to a device, such as device 114, or to a power supply/storage module 112.

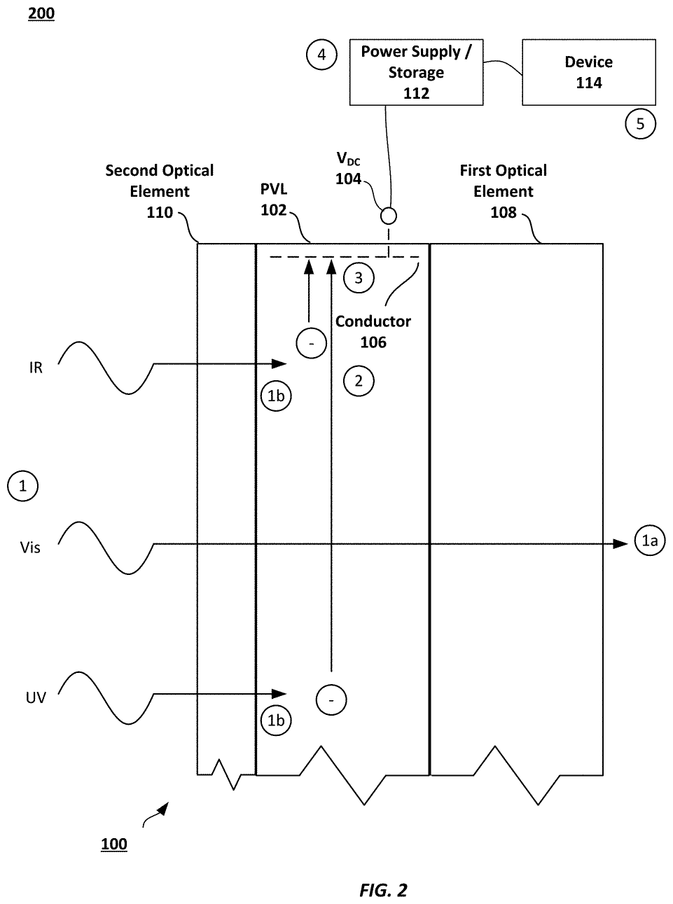

FIG. 2 is a schematic diagram 200 illustrating example operation of a device 114 that is coupled to an optical assembly 100 with a photovoltaic layer 102 in accordance with embodiments of the present disclosure. Light, such as sunlight or from other sources, can include visible light and UV and NIR light. 1) The light can impinge the optical assembly 100. 1a) At least some of the visible light can transmit through the second optical element 110, the PVL 102, and the first optical element 108. 1b) The UV and NIR light can transmit through the second optical element 110 and at least some of the UV and NIR light can be absorbed by the PVL 102. 2) The UV and NIR light can excite electrons or other charge carriers in the PVL 102 (e.g., electron-hole creation). 3) Free electrons can drift to conductor 106 to generate electricity. 4) Electricity can be received by power supply/storage module 112, which can 5) supply power to a device 114.

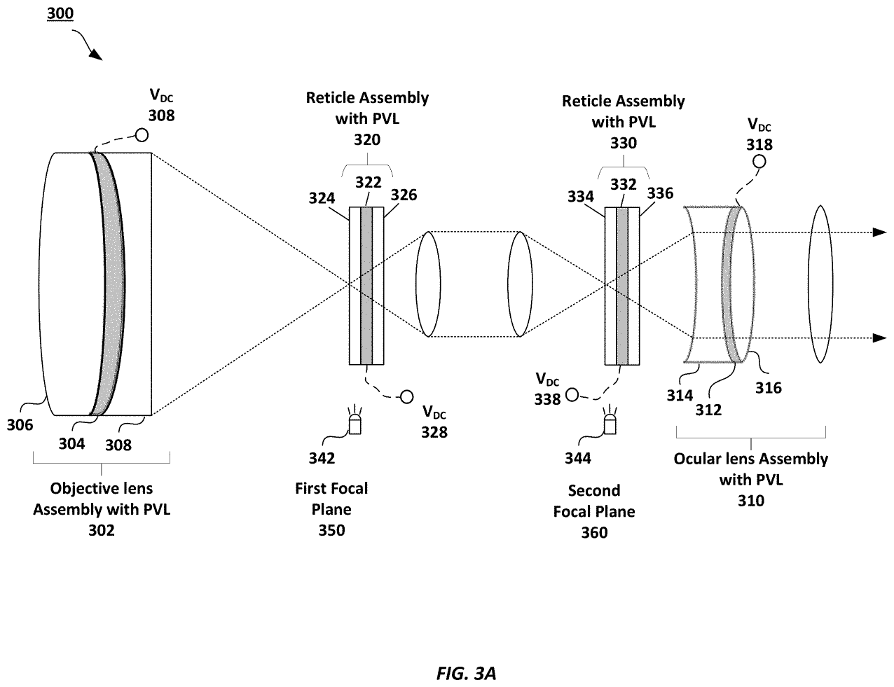

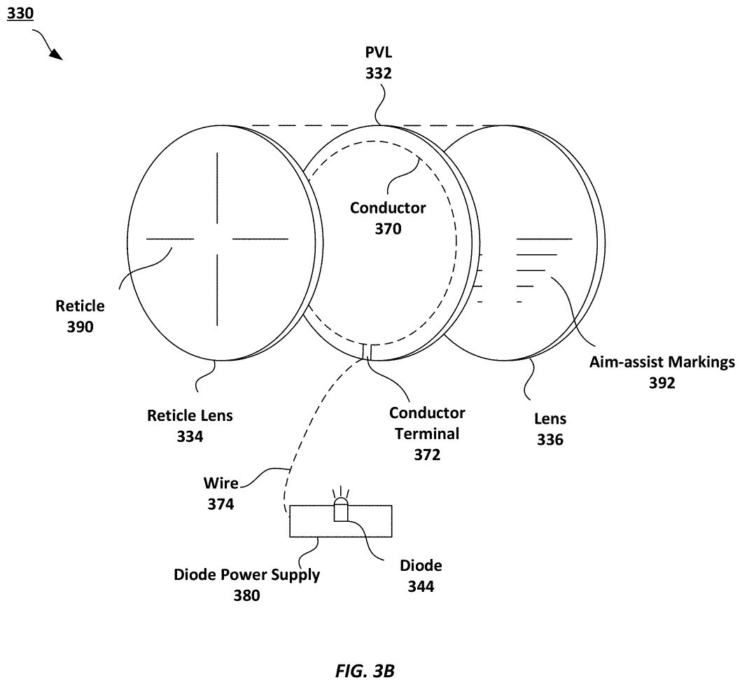

FIG. 3A is a schematic diagram of an example optical device 300 that includes various optional locations for optical assemblies with a photovoltaic layer in accordance with embodiments of the present disclosure. Optical device 300 can be a scope, such a rifle scope. Optical device 300 is illustrated as a rifle scope byway of example. It is understood, however, that optical device 300 can be a telescope, spyglass, spotting scope, or other type of scope that uses optical lenses to magnify and/or focus distant objects, including an infrared scope, night-vision scope, binoculars, or other optical device.

Optical device 300 can include a plurality of optical elements. For example, the optical device 300 can include an objective lens assembly 302, an ocular lens assembly 310, and one or more reticle assemblies, such as first and second reticle assemblies 320 and 330, respectively. Any one or a combination of the aforementioned optical elements can include a photovoltaic layer for generating electricity.

In a first example, an objective lens assembly 302 includes a PVL 304 between a first lens 306 and a second lens 308. The object lens assembly 302 (including PVL 304) can transmit visible light through the optical pathway (e.g., towards the first focal plane 350). PVL 304 can absorb UV and NIR light to output electricity 308.

In another example, an ocular lens assembly 310 can include a PVL 312 between two lenses: a first lens 314 and a second lens 316. The ocular lens assembly 310 (including the PVL 312) can receive light through the scope tube and transmit visible light to a user's eye. The PVL 312 can absorb UV and NIR light to output electricity 318.

In some embodiments, the optical device 300 can include a reticle assembly 320 that includes a PVL 322 between two lenses: a first lens 324 and a second lens 326. First lens 324 and/or second lens 326 can include an etched reticle or other etched aim-assist markings. The PVL 322 can provide power from an output 328 to an light source 342. Light source 342 can illuminate the reticle assembly, which can cause the etched reticle to be illuminated (e.g., the etched reticle can scatter or reflect light from the diode, giving the reticle the appearance of being lit or illuminated as a user looks through the scope tube). Light source 342 can be a light emitting diode (LED), laser, point source, fiber optic, lamp, or other light source.

Reticle assembly 320 is shown to reside proximate to a first focal plane 350. First focal plane can be proximate to the object lens assembly 302. In embodiments, a reticle assembly 330 can reside proximate a second focal plane 360, proximate the ocular lens assembly 310. Reticle assembly 330 includes a PVL 332 between two lenses: a first lens 334 and a second lens 336. First lens 334 and/or second lens 336 can include an etched reticle or other etched aim-assist markings. The PVL 332 can provide power from an output 338 to an light source 344. Light source 344 can illuminate the reticle assembly, which can cause the etched reticle to be illuminated (e.g., the etched reticle can scatter or reflect light from the diode, giving the reticle the appearance of being lit or illuminated as a user looks through the scope tube). Light source 344 can be a light emitting diode (LED), laser, point source, fiber optic, lamp, or other light source.

FIG. 3B is a schematic diagram of an example reticle lens assembly 330 with a photovoltaic layer 332 in accordance with embodiments of the present disclosure. The reticle lens assembly 330 is shown in an exploded view to illustrate the aim-assist markings that can be etched onto the lenses. For example, a cross-hair reticle 390 can be etched or placed onto reticle lens 334. Aim-assist markings 392 can be etched or placed onto lens 336. Other configurations and markings other than what is shown are also contemplated. PVL 332 can reside between the reticle lens 334 and lens 336. The PVL 332 can be bonded to lenses 334 and 336 using transparent or clear adhesives, resins, bonding agents, glues, etc.

A PVL 332 can include a conductor 370 to conduct charge towards the conductor terminal (an electrical output or node) 372. A wire 374 can be bonded, soldered, or otherwise connected to the conductor terminal 372 to conduct electricity generated by the PVL 332 to a device. In this example, the reticle lens assembly 330 can be illuminated by an LED 344. The PVL 332 can provide power to the diode power supply 380, which can supply power to the LED 344.

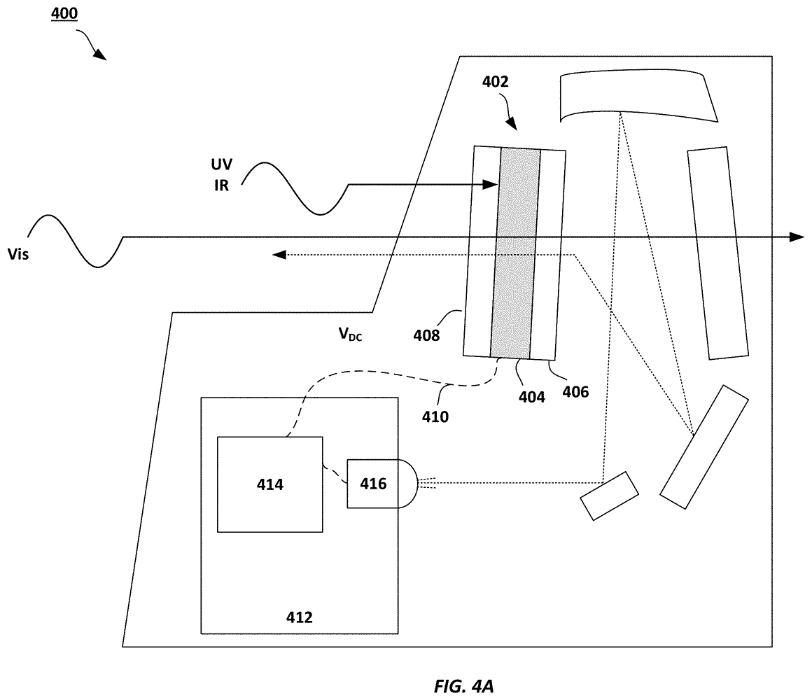

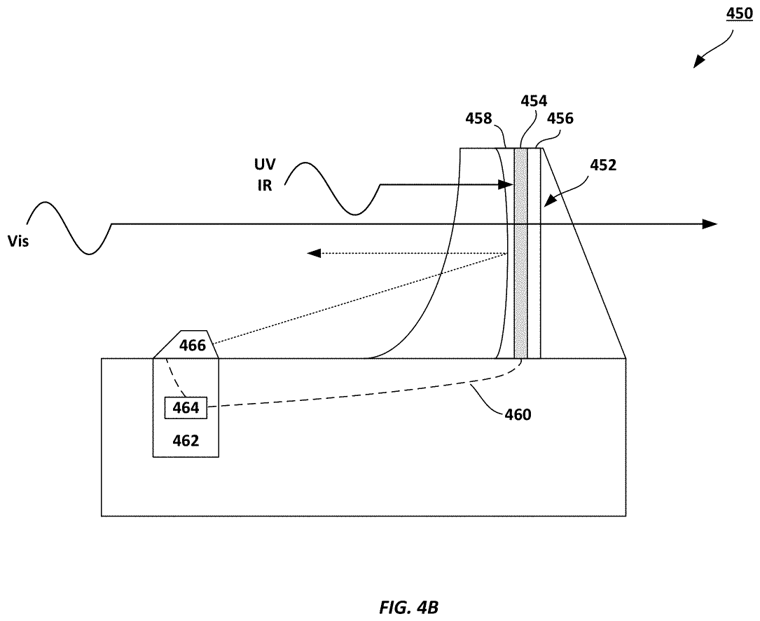

FIGS. 4A-B a schematic diagram of example optical devices that includes an optical assembly with a photovoltaic layer in accordance with embodiments of the present disclosure. FIG. 4A is a schematic diagram of an example optical device 400 at least partially powered by a photovoltaic element 404 in accordance with embodiments of the present disclosure. The optical device 400 can include a light emission device 412. Light emission device 412 can include a power supply 414 and a light emission source 416. Light emission source 416 can be a laser, diode, hologram emitter, or other source of coherent light. The optical device 400 can include an optical train that includes an optical assembly 402. Optical assembly 402 can include a photovoltaic element 404 between two lens 406 and 408. The optical assembly 402 can be similar that described in FIG. 1. The lenses 406 and 408 and the photovoltaic element 404 can be transparent or semi-transparent for light in the visible spectrum. In embodiments, light emitted from light emission source 416 can at least partially be reflected by one or more of lenses 406 and/or 408. For example, a hologram of a circular or cross-hair sight can be visible to a user looking down an axis of the optical assembly 402. Photovoltaic element 404 can absorb light in the UV and/or NIR range to generate electricity.

Photovoltaic element 404 can output electricity by a wire 410 to the light emission device 412 and supply power to the power supply 414. Power supply 414 can, in some embodiments, also receive power from a battery or other power source, and the photovoltaic element 404 can augment power delivered to the power supply 414.

FIG. 4B is a schematic diagram of another example optical device 450 at least partially powered by a photovoltaic element 454 in accordance with embodiments of the present disclosure. The optical device 450 can include a light emission device 462. Light emission device 462 can include a power supply 464 and a light emission source 466. Light emission source 466 can be a laser, diode, hologram emitter, or other source of coherent light. The optical device 450 can include an optical train that includes an optical assembly 452. Optical assembly 452 can include a photovoltaic element 454 between two lens 456 and 458. The optical assembly 452 can be similar that described in FIG. 1. The lenses 456 and 458 and the photovoltaic element 454 can be transparent or semi-transparent for light in the visible spectrum. Photovoltaic element 454 can absorb light in the UV and/or NIR range to generate electricity. In embodiments, light emitted from light emission source 466 can at least partially be reflected by one or more of lenses 456 and/or 458. For example, a hologram of a dot or circular or cross-hair sight can be visible to a user looking down an axis of the optical assembly 452.

Photovoltaic element 454 can output electricity by a wire 460 to the light emission device 462 and supply power to the power supply 464. Power supply 464 can, in some embodiments, also receive power from a battery or other power source, and the photovoltaic element 454 can augment power delivered to the power supply 464.

In embodiments, optical device 400 or 450 can be mounted onto another device, such as a rifle, handgun, or other type of armament. Optical device 400 or 450 can provide aiming assist functions for a user of the armament.

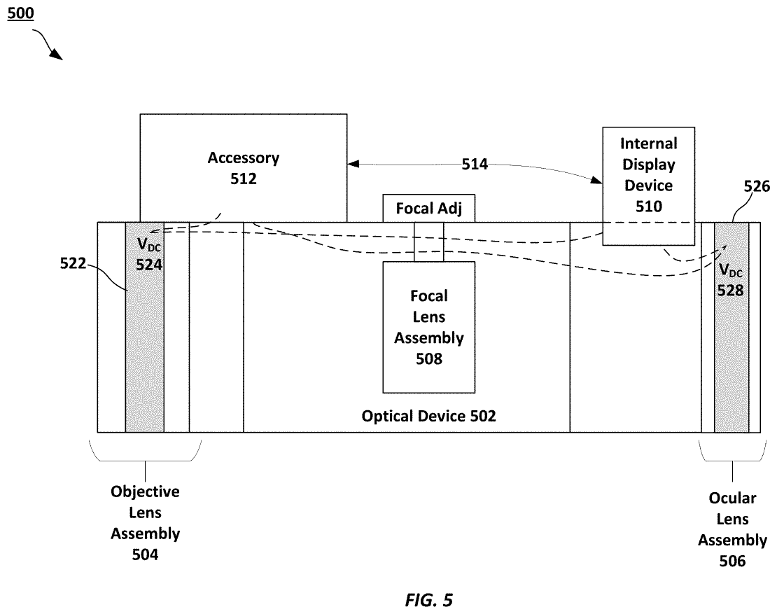

FIG. 5 is a schematic diagram of another example optical device 502 that includes an optical assembly with a photovoltaic layer and an internal display device 510 in accordance with embodiments of the present disclosure. System 500 can include an accessory 512 coupled to the optical device 502. The optical device 502 can include a series of lenses, an objective lens assembly 504 and an ocular lens assembly 506. Other lens assemblies can also be included, such as a focal lens assembly 510 as described in FIG. 3.

The optical device 502 can also include an internal display device 510. Internal display device 510 can be linked to the accessory 512 by a cable 514 to display information provided by the accessory to a user looking down the long axis of the optical device 502. Internal display device 510 can send optical information to the accessory 512 for processing or transmission. The internal display device 510 can include one or more powered features, such as a light emission device, a powered mechanism to move optics in and out of the field of vision of the user, and other powered features.

In some embodiments, objective lens assembly 504 can include a photovoltaic element 522 between two lenses or optical elements. The photovoltaic element 522 can transmit visible light and absorb UV and/or NIR light. Absorption of UV and NIR light can excite charge carriers to generate electricity, which can be output via a node 524. Electricity generated from the photovoltaic element 522 can be used to at least partially power the internal display device 510 or the accessory 512.

In some embodiments, ocular lens assembly 506 can include a photovoltaic element 526 between two lenses or optical elements. The photovoltaic element 526 can transmit visible light and absorb UV and/or NIR light. Absorption of UV and NIR light can excite charge carriers to generate electricity, which can be output via a node 528. Electricity generated from the photovoltaic element 526 can be used to at least partially power the internal display device 510 or the accessory 512.

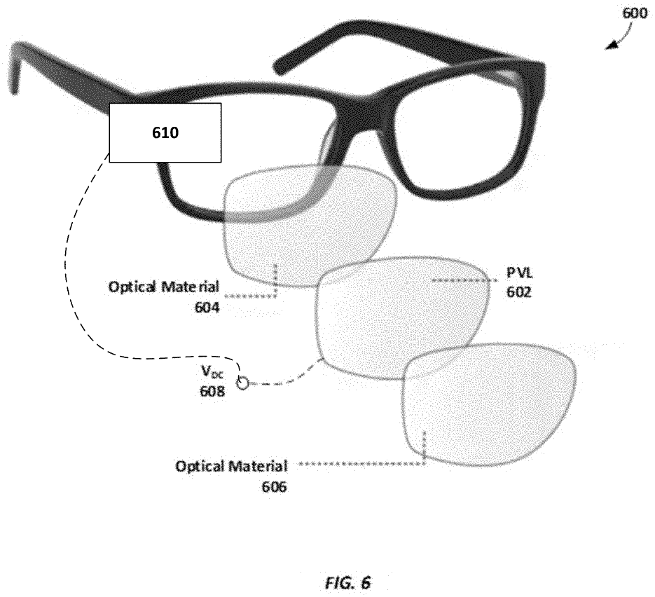

FIG. 6 is a schematic diagram of an example wearable optical device 600 that includes an optical assembly with a photovoltaic layer 602 in accordance with embodiments of the present disclosure. Wearable optical device 600 can be a pair of glasses, sunglasses, goggles, virtual reality or augmented reality wearable device, or other wearable device. The optical assembly can include a photovoltaic element 602 between two optical materials 604 and 606. Optical materials can include lenses, coatings, or other optically transparent materials. Optical assembly can be transparent or semi-transparent to visible light, and the photovoltaic element 602 can absorb UV and/or NIR light to excite charge carriers to generate electricity.

The wearable optical device 600 can include a device 610. Device 610 can be powered or partially powered by the electricity generated by the photovoltaic element 602. The device 610 can be a display device. Display device can provide augmented reality displays, metrics, infrared or night vision displays, target acquisition information, distance information, heart rate, cadence, steps, compass information, inventory count, or other information to a wearer of the wearable optical device 600. Device 610 can also include wired or wireless transmission and/or reception of information (e.g., via Bluetooth or other radio transmission/reception mechanism). The photovoltaic element 602 can also provide power to the transmission/reception mechanism.

Although the foregoing embodiments have been described in some detail to facilitate understanding, the described embodiments are to be considered illustrative and not limiting. It will be apparent to one of ordinary skill in the art that certain changes and modifications can be practiced within the scope of the appended claims.

What is claimed is:

1. An apparatus comprising:
a first optical element and a second optical element, the first and second optical elements transparent to visible light; and
a photovoltaic element residing between the first optical element and the second optical element, the photovoltaic element transparent to visible light, the photovoltaic element to generate electricity based on the absorption of ultraviolet (UV) and near-infrared (NIR) light;
the photovoltaic element comprising a conductive element to conduct electricity generated from the absorption of UV and NIR light.

2. The apparatus of claim 1, wherein one or both of the first or second optical elements comprise a lens.

3. The apparatus of claim 1, wherein one or both of the first or second optical elements comprises an aim assist marking.

4. The apparatus of claim 3, wherein the aim assist marking comprises a reticle.

5. The apparatus of claim 1, wherein the conductor is coupled to a wire by a wire-bond or a solder bond.

6. The apparatus of claim 1, wherein the first or second optical material comprises an optically transparent coating.

7. The apparatus of claim 1, wherein the photovoltaic element comprises an organic active layer.

8. A system comprising:
an optical assembly comprising:
a first optical element and a second optical element, the first and second optical elements transparent to visible light; and
a photovoltaic element residing between the first optical element and the second optical element, the photovoltaic element transparent to visible light, the photovoltaic element to generate electricity based on the absorption of ultraviolet (UV) and near-infrared (NIR) light;
the photovoltaic element comprising a conductive element to conduct electricity generated from the absorption of UV and NIR light;
a light emission device electrically connected to the conductive element; the photovoltaic element to provide electricity to the light emission device.

9. The system of claim 8, wherein the light emission device comprising a power supply, the conductive element electrically connected to the light emission device through the power supply, the power supply to provide power to the light emission device.

10. The system of claim 8, wherein one or both of the first or second optical elements comprises an aim assist marking; and
wherein the light emission device is positioned to illuminate the first or second optical elements.

11. The system of claim 10, wherein the aim assist marking comprises a reticle.

12. The system of claim 8, wherein the system comprises a display device, and wherein light emission device is to illuminate the internal display device.

13. The system of claim 8, wherein the light emission device comprises a laser or light emitting diode.

14. The system of claim 8, further comprising an optical train to reflect light emitted from the light emission device to one or both of the first or second optical element.

15. The system of claim 8, wherein the system comprises a scope, the scope housing the optical assembly.

16. The system of claim 8, wherein the scope houses the light emission device.

17. The system of claim 8, wherein the system comprises a holographic sight or a red-dot sight, and wherein the light emission device comprises a holographic emitter or a red-dot emitter.

18. The system of claim 8, wherein the system comprises a wearable optical device, the optical assembly secured by the wearable optical device.

19. The system of claim 18, wherein the wearable optical device comprises one of glasses, sunglasses, goggles, or augmented reality lenses.

20. The system of claim 18, wherein the wearable optical device comprises a display device, the display device electrically connected to the photovoltaic element.
